(19) United States
(12) Patent Application Publication
(10) Pub. No.: US 2025/0345939 A1
(43) Pub. Date: Nov. 13, 2025

(54) Component Pick-and Place System, Device and Method thereof

(71) Applicant: Semiconductor Technologies & Instruments Pte Ltd, Singapore (SG)

(72) Inventors: Haitao WEI, Singapore (SG); Chingshu LIU, Singapore (SG)

(21) Appl. No.: 19/102,850

(22) PCT Filed: May 26, 2023
(86) PCT No.: PCT/SG2023/050370

§ 371 Date: Feb. 10, 2025

(30) Foreign Application Priority Data
Aug. 12, 2022 (SG) 10202250724V
Dec. 16, 2022 (SG) 10202260477V

(51) Int. Cl. B25J 9/16; B25J 9/00; B25J 15/06; H01L 21/67

(52) U.S. Cl. CPC B25J 9/1687; B25J 9/0093; B25J 15/0683; H01L 21/67144

(57) ABSTRACT

There is a component pick-and-place system having a control unit, at least one transport line for transporting a plurality of component trays; and at least one transfer line for transferring a plurality of pick-and-place (PnP) devices. Each of the plurality of PnP devices has a control and valve unit, an automatic pitch conversion unit having at least one column/module and at least one row of pickup tips positional at a parking area and an active area. The automatic pitch conversion unit has a X-pitch conversion mechanism and a Y-pitch conversion mechanism. The X-pitch conversion mechanism has a first drive motor, a plurality of movement transfer elements for transferring rotary motions of the first drive motor to cause a pair of X-pitch bands to move in a linear direction, and a pair of engagement arms that are slidably engaged to the pair of X-pitch bands for sequentially engaging a column of pickup tips to move to a desired X-pitch position. The Y-pitch conversion mechanism has a second drive motor, a plurality of movement transfer elements for transferring rotary movements of the second drive motor to a pair of Y-pitch arms to cause a pair of Y-pitch rods to move in a linear direction, and a pair of pickup tip holders slidably engaged to the pair of Y-pitch rods for simultaneously moving the plurality of rows of pickup tips to a desired Y-pitch position.

### FIELD OF THE INVENTION

This invention relates to handling systems for semiconductor component pick-and-place operations and more particularly to a pick-and-place system, device and method having a plurality of pick-and-place stations and self-contained pick-and-place devices that are capable of automatic pitch conversions in X and Y coordinates.

### BACKGROUND

The handling and transferring of semiconductor components between different packaging media or workstations is a time consuming and repetitive process. Such processes including pick-and-place operations are automated for technical and/or efficiency reasons, electrostatic discharge (ESD) protection, as well as to avoid physical damage to the components. With the increasing market competition in semiconductor component fabrication and processing, there is a continuous need to increase the speed and throughput of existing component handling systems and devices for pick-and-place operations.

To increase machine throughput, multiple pickup heads are utilised in pick-and-place devices so that several components can be picked and placed at the same time. Different products may utilise components of varied sizes such that the size of the tray pockets including the pitch between components will be different. Inspection operations may also allow only specific numbers of components to be inspected at the same time. Therefore, the number of pickup tips and the pitch in between them must be configured to cater to the various component sizes and processing capacity of the machine.

Conventional pick-and-place devices are usually designed as a single device having a plurality of pickup tips arranged in a single row. Such devices are capable of automatic pitch conversion according to the various products and processing capacity. These devices are however slow and cannot meet machine throughput targets desired by manufacturers today.

Prior art U.S. Pat. No. 9,776,334 discloses an apparatus for automatic pitch conversion for pick-and-place heads, comprising two external auto pitch station for adjusting the pitch of pickers/grippers of a pick-and-place device in X and Y coordinates. The apparatus is capable of picking up components from one type of tray, transfer the components to another type of tray and/or to and from an inspection station. The automatic pitch conversion mechanisms located at the pair of auto pitch stations are used for adjusting the spacing (pitch) of the pickup tips. However, since there is only one pair of auto pitch stations, they must be shared between multiple pickup devices. Therefore, when a need for pitch conversion arises, the pick-and-place devices are moved sequentially by a transport system, i.e. one at a time to the pair of external auto pitch stations in order for the pitch conversion to take place.

In order to address or alleviate the above shortcomings, a pick-and-place system, device and method having multiple pick-and-place stations and self-contained pick-and-place devices that are capable of automatic pitch conversions in the X and Y coordinates is disclosed herein to enable further increases in machine throughput.

### SUMMARY

In an aspect, there is a a component pick-and-place system comprising a control unit, at least one transport line for transporting a plurality of component trays; and at least one transfer line for transferring a plurality of pick-and-place (PnP) devices. Each of the plurality of PnP devices comprises a control and valve unit, an automatic pitch conversion unit having at least one column and at least one row of pickup tips positional at a parking area and an active area. The automatic pitch conversion unit further comprises a X-pitch conversion mechanism comprising a first drive motor, a plurality of movement transfer elements for transferring rotary motions of the first drive motor to cause a pair of X-pitch bands to move in a linear direction, and a pair of engagement arms slidably engaged to the pair of X-pitch bands for sequentially engaging each of the at least one column of pickup tips to move to a desired X-pitch position. The automatic pitch conversion unit further comprises a Y-pitch conversion mechanism comprising a second drive motor, a plurality of movement transfer elements for transferring rotary movements of the second drive motor to a pair of Y-pitch arms to cause a pair of Y-pitch rods to move in a linear direction, and a pair of pickup tip holdersslidably engaged to the pair of Y-pitch rods for simultaneously moving the at least one row of pickup tips to a desired Y-pitch position.

In some embodiments, the X-pitch mechanism comprises a first pair of guide rails and each of the plurality of columns of pickup tips is sequentially moved to the X-pitch position along the first pair of guide rails.

In some embodiments, the X-pitch mechanism comprises a second pair of guide rails spaced apart from the first pair of guide rails and each of the plurality of columns of pickup tips is sequentially moved to the X-pitch position along the second pair of guide rails.

In some embodiments, each of the plurality of columns of pickup tips is sequentially moved along the first pair of guide rails followed by the second pair of guide rails, wherein the X-pitch between each column is variable.

In some embodiments, each of the plurality of PnP devices is configured to pick components from the component trays along the transport line, conduct Y-pitch conversion on-the-fly and place the components in the component trays along another transport line.

In some embodiments, the Y-pitches at the transport lines are different.

In some embodiments, the component pick-and-place system has a programmable software recipe configured to execute commands for X-pitch and Y-pitch conversions.

In some embodiments, the X-pitch conversion mechanism further comprises one or more column sensors configured to determine the actual positions of the pickup tips in an X-pitch direction and wherein the Y-pitch conversion mechanism further comprises one or more row sensors configured to determine the actual positions of the pickup tips in a Y-pitch direction.

In some embodiments, a suction portion of each pickup tip is configured to be removed with a quick release mechanism.

In some embodiments, each of the pair of engagement arms comprises a pin cylinder and a pusher, and wherein the control and valve unit is configured to activate the pin cylinder to enable the pusher to engage or disengage the pair of engagement arms.

In some embodiments, each of the at least one row of pickup tips is adapted to be slidably attached to the pair of Y-pitch rods such that each of the at least one row of pickup tips is simultaneously moved for Y-pitch conversion.

In some embodiments, the Y-pitch conversion mechanism comprises one or more link arms adapted to transfer rotary movement of the second drive motor to the pair of Y-pitch arms, and wherein the length of the one or more link arms is extendible to facilitate an increase in the numbers of rows of pickup tips.

In some embodiments, the component pick-and-place system comprises a balancing mechanism adapted to be in synchronous motion with the Y-pitch conversion mechanism, the balancing mechanism being connected to the Y-pitch conversion mechanism via a shaft.

In some embodiments, the automatic pitch conversion unit further comprises a pantograph mechanism configured to keep the pitch between each row of pickup tips equidistant from each other.

According to another aspect of the disclosure, there is a pick-and-place (PnP) device for transferring semiconductor components. The PnP device comprising a plurality of pick-and-place (PnP) modules, each PnP module comprising at least three pick-and-place (PnP) heads; a transfer mechanism for moving each of the plurality of PnP modules to a component X-pitch position above a tray or workstation. The transfer mechanism comprising a first drive motor; a plurality of movement transfer elements for transferring rotary motions of the first drive motor to cause a pair of X-pitch bands to move in a linear direction; and a pair of engagement arms slidably engaged to the pair of X-pitch bands for sequentially engaging each of the plurality of PnP modules to move to a component X-pitch position. The PnP device comprises a pitch adjustment mechanism for adjusting the Y-pitch of the at least three pick-and-place heads. The pitch adjustment mechanism comprises a second drive motor; a plurality of movement transfer elements for transferring rotary movements of the second drive motor to a pair of Y-pitch arms to cause a pair of Y-pitch rods to move in a linear direction; and a pair of pickup tip holders slidably engaged to the pair of Y-pitch rods for simultaneously moving the plurality of rows of pickup tips to a desired Y-pitch position.

In some embodiments, the transfer mechanism comprises a first pair of guide rails and each of the plurality of PnP modules is sequentially moved to the X-pitch position along the first pair of guide rails.

In some embodiments, the transfer mechanism comprises a second pair of guide rails and each of the plurality of PnP modules is sequentially moved to the X-pitch position along the second pair of guide rails.

In some embodiments, each of the plurality of PnP modules is sequentially moved along the first pair of guide rails followed by the second pair of guide rails, and wherein the X-pitch between each column is variable.

In some embodiments, the pitch adjustment mechanism further comprises a pair of pickup tip holders slidably engaged to the pair of Y-pitch rods for simultaneously moving the plurality of rows of pickup tips to a desired Y-pitch position.

In some embodiments, the pitch adjustment mechanism comprises one or more link arms adapted to transfer rotary movement of the second drive motor to the pair of Y-pitch arms, and wherein the length of the one or more link arms is extendible to facilitate an increase in the numbers of rows of pickup tips.

According to another aspect of the disclosure, there is a method of automatic pitch conversion for a component pick-and-place system, comprising the steps of selecting the component to run with the recipe in the control unit, obtaining the tray format or matrix information from the recipe, determining with the control unit, whether the X and Y pitches of the tray matrix are identical to the PnP device; and inputting a command with the control unit to carry out X-pitch and/or Y-pitch conversion on the PnP device when the X and Y pitches are determined not to be identical.

In some embodiments, the method may further comprise the step of moving each column of pickup tips to a parking area of the PnP device, and thereafter scanning to determine the X-pitch position of the pickup tips in the parking area.

In some embodiments, the method may further comprise the step of sequentially moving each column of pickup tips from the parking area to the correct X-pitch position in the active area.

In some embodiments, the method may further comprise the step of scanning each column of pickup tips at the active area to confirm the X-pitch positions of the pickup tips.

In some embodiments, the method may further comprise the step of moving each row of pickup tips to a home position whereby the Y-pitch between each pickup tip is at a minimum.

In some embodiments, the method may further comprise the step of simultaneously moving each row of pickup tips to the correct Y-pitch positions.

In some embodiments, the method may further comprise the step of scanning each row of pickup tips to confirm that the pickup tips are in the correct Y-pitch positions in the active area.

In some embodiments, the control unit is configured to input a command to carry out X-pitch and/or Y-pitch conversion on the PnP device when the X and/or Y pitches are still determined not to be identical.

### DRAWINGS

In the figures, which illustrate, by way of example only, embodiments of the present disclosure,

FIG. 1 is a top view of a pick and place system showing multiple PnP devices and tray transportation lines, in accordance with embodiments of the disclosure;

FIG. 2A is a top view of a PnP device placed across or perpendicular to a longitudinal axis of a JEDEC tray;

FIG. 2B is a top view of a PnP device placed along or in line to a longitudinal axis of the JEDEC tray;

FIG. 3 is a schematic block diagram of the control system in accordance with embodiments of the disclosure;

FIG. 4 is a perspective view showing a configuration of the PnP device in relation to the tray and the pickup tips in accordance with embodiments of the disclosure;

FIG. 5 is an exploded view showing the chassis, control and valve unit and automatic pitch conversion unit;

FIG. 6 is a close-up view of an automatic pitch conversion unit showing the X and Y pitch conversion mechanisms with rows A,B,C and columns M,N,O,P,Q of the pickup tips;

FIG. 7 is a top perspective view of the automatic pitch conversion unit showing the X-pitch conversion mechanism;

FIG. 8 is a top angle view of the automatic pitch conversion unit showing the X-pitch conversion mechanism;

FIG. 9 is a section view showing the X-pitch conversion mechanism;

FIG. 10A is a side view showing details of the X-pitch conversion mechanism;

FIG. 10B is a section view showing details of the left engagement arm of FIG. 9;

FIG. 11A is a perspective view of the Y-pitch pickup tips at an open position;

FIG. 11B is a perspective view of the Y-pitch pickup tips at a closed (home) position;

FIG. 11C is a perspective view of two PnP columns/modules slidable along respective pairs of guide rails to sequentially position each of the PnP modules in accordance with another embodiment of the disclosure;

FIG. 12 is a top perspective view showing the Y-pitch conversion mechanism;

FIG. 13 is a side perspective view showing the Y-pitch conversion mechanism;

FIG. 14 is a bottom perspective view showing the Y-pitch conversion mechanism;

FIG. 15 is atop view showing scalability of the pickup tips that can be configured in the Y-pitch columns;

FIG. 16 is a schematic flow diagram showing a process control system;

FIG. 17 is a schematic flow diagram of pitch conversion in X-pitch for a column of pickup tips;

FIG. 18 is a schematic flow diagram of pitch of configurable conversion in Y-direction for a row of pickup tips.

### DETAILED DESCRIPTION

The disclosure was conceptualized to provide a pick-and-place system, device and method having multiple pick-and-place stations and self-contained pick-and-place devices that are capable of automatic pitch conversions in the X and Y coordinates. Accordingly, this enables further increases in machine throughput.

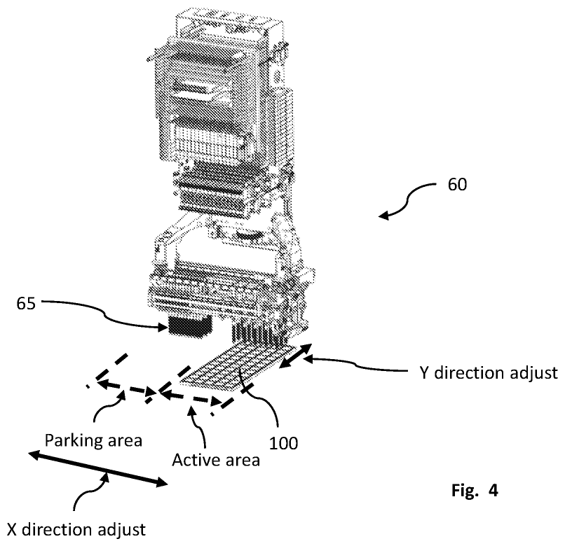

In order to illustrate the technical solution(s) to the embodiments of the present disclosure, embodiments of the present disclosure are described with reference to the drawings. It is appreciable that the drawings referred to are some examples or embodiments of the present disclosure. A person having ordinary skill in the art, without further creative efforts, may apply the present disclosure to other scenarios according to these drawings. For example, although the drawing in FIG. 4 shows a total of 48 pickup tips, a person having ordinary skill in the art and without creative efforts would be able to apply the present disclosure to any numbers of pickup tips in either the X-pitch direction or Y-pitch direction to fulfil the maximum required by the user or machine capacity.

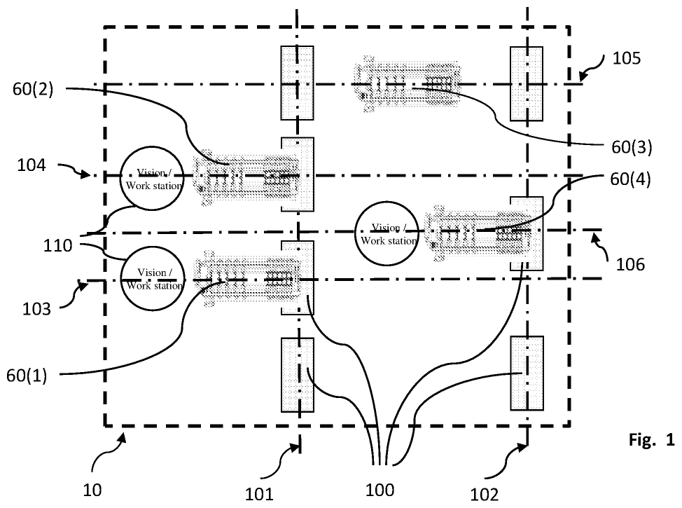

Referring to FIG. 1, a pick and place system 10 includes a plurality of pick-and-place devices 60 [PnP hereinafter] and a plurality of trays 100. Transport lines carry the plurality of PnP devices 60 and trays 100 along several separate lines respectively. As shown in FIG. 1, PnP devices 60 can be placed over several trays 100 located along a set of tray transport lines 101, 102. The PnP devices 60 can be carried along another distinct set of PnP device transfer lines 103, 104, 105, 106 to pick and/or place components from/onto a tray and/or a workstation 110. Likewise, a tray 100 can be transported along transport lines 101, 102 for transferring or transporting the components to another location.

The numbers of transfer lines 101, 102, 103, 104, 105, 106 are scalable and are only limited by the capacity of the machine space and footprint. In this way, pitch conversions can take place simultaneously with several PnP devices 60 in operation at the same time. This is unlike prior art systems where only a single PnP device along a single axis or direction can be utilised. In this example as illustrated in FIG. 1, JEDEC trays 100 (or other carriers) move along lines 101 and 102, while four PnP devices 60(1), 60(2), 60(3) and 60(4) move along lines 103, 104, 105 and 106. The device 60(1) can pick-up components from a tray 100 anywhere along lines 101 to a workstation to conduct, for example a vision inspection and return to its original location along line 103. Device 60(2) can separately pick up components from a tray 100 anywhere along lines 101 to another location such as another tray or workstation and return to its original location along transfer line 104. Device 60(3) can separately pick up components from a tray 100 anywhere along transport lines 101 and 102 and place them at another location such as another tray or workstation 110 and return to its original location along transfer line 105. Device 60(4) can separately pick up components from a tray 100 to yet another workstation 110 and place them at another location such as another tray or workstation and return to its original location along transfer line 106.

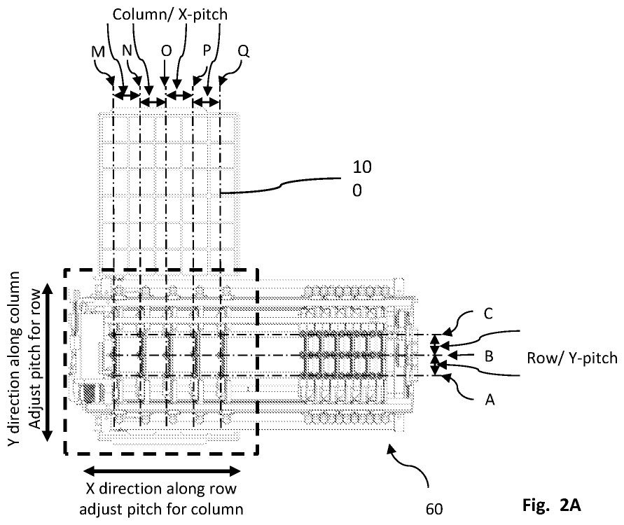

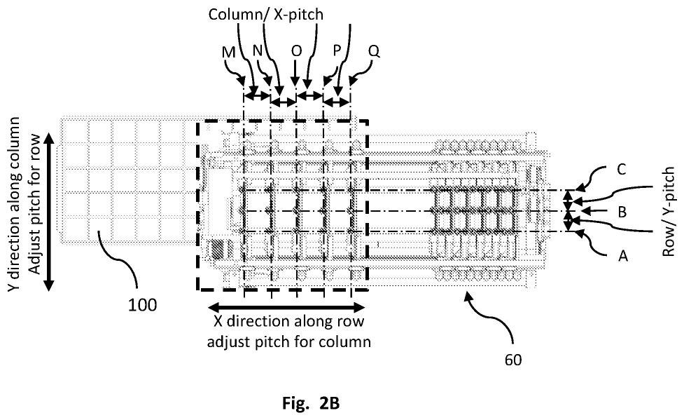

While FIG. 1 shows that the PnP devices and transport lines are perpendicular to each other, it is possible for the transfer/transport lines to be arranged at different angles with respect to each other to maximise machine space. Each PnP device 60 can be configured to move to any of the trays and/or workstations as desired. In this way, the number of PnP operations is only limited by the numbers of transfer lines possible in the system 10. One skilled in the art will understand that the axes of the PnP and tray transport lines are interchangeable with each other such that the PnP devices can be transported along any of these two axes to maintain flexibility of the machine layout. This is illustrated in FIGS. 2A and 2B where the trays are positioned in a direction perpendicular and inline to/with each other respectively. Thus, a user can program as many PnP devices 60 as necessary to maximise the system configuration to enable an optimum throughput for the machine for each product run.

FIGS. 2A and 2B illustrate how a JEDEC tray 100 can be placed below a PnP device 60 for retrieval of components. JEDEC trays are also known as “matrix” trays since the components are nested into pockets in fixed position rows and columns. The spacing (pitch) of each component pocket (cells) is defined by JEDEC standards. This allows automated PnP machines to dimensionally locate and pick up the components from the tray and place them onto another media or workstation. In this disclosure, tray X (lateral) and Y (longitudinal) coordinates are used as a reference for the X and Y pitches of the PnP device pickup tips for singularity of reference. Therefore, the Y-pitch is described as along the lateral direction of the PnP device and the X-pitch is along the longitudinal direction of the PnP device 60 throughout this disclosure.

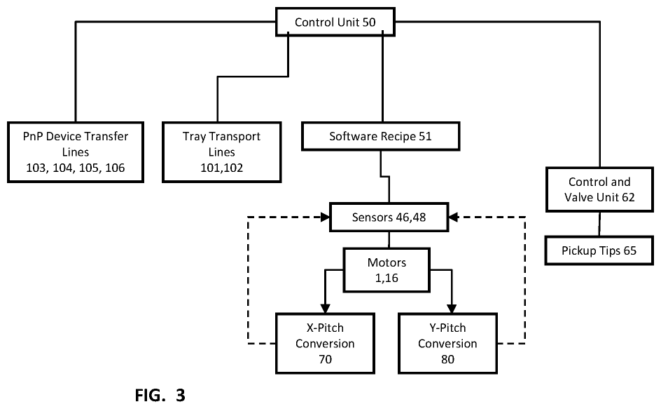

FIG. 3 shows a schematic block diagram of a control unit 50. The control unit 50 can control the operations of multiple configurable sets of tray transportation lines and PnP transfer lines and further provides the instructions to the control and valve unit 62 to operate the PnP device and pickup tips. A software recipe 51 and associated sensors 46, 48 are configured to execute commands to the X and Y pitch motors 1, 16 for the column (X-pitch) and row (Y-pitch) conversions. The X and Y pitches for different tray matrices can be easily programmed on the software recipe 51. The control and valve assembly 62 further includes a plurality of control valves for performing the pneumatic pick and place operations.

FIG. 4 shows a configuration of the PnP device 60 in relation to the tray and the pickup tips. A set of inactive pickup tips 65 is parked at an end portion (parking area) of the PnP device 60 and another set of active pickup tips 65 is positioned at the other end portion (active area) of the PnP device. The active pickup tips 65 at the active area are used for picking up and depositing components from a tray such as the JEDEC tray 100 shown in FIGS. 2A and 2B or to a workstation 110 such as an inspection station shown in FIG. 1. Although FIG. 4 shows a total of 48 pickup tips, the numbers of pickup tips are only limited to the maximum required by the user or machine capacity. Any numbers of pickup tips 65 are possible in either the X-pitch direction or Y-pitch direction.

As illustrated in FIGS. 2A and 2B, the number of pickup tips 65 includes three rows A, B, C of three pickup tips 65 arranged in a row at equal distances (Y-pitch) from each other in the Y-pitch direction. However, the numbers of rows of pickup tips 65 while shown as three in this disclosure, are variable, and can be configured from one to as many as determined by the user during the initial configuration or changeover of a product run. Each column of pickup tips may also be referred to as a pick-and-place module as each column or module can be moved to a location corresponding to an X-pitch position above a tray or workstation individually. The pickup tips 65 in each module can thus be configured as an assembly to be moved to the X-pitch position from the parking area to the active area as illustrated in FIG. 4. For Y-pitch conversion, the pickup tip 65 in row B at the center of the row or module is in a fixed position for a three pickup tip configuration while the other 2 pickup tips (rows A and C) can be moved towards or away from the center pickup tip in row B to change the Y-pitch. The terms “column(s)” and “module(s)” will be used interchangeably hereafter in this disclosure. However, for ease of explanation, the term “column(s)” will be used when describing the pitch conversion mechanisms.

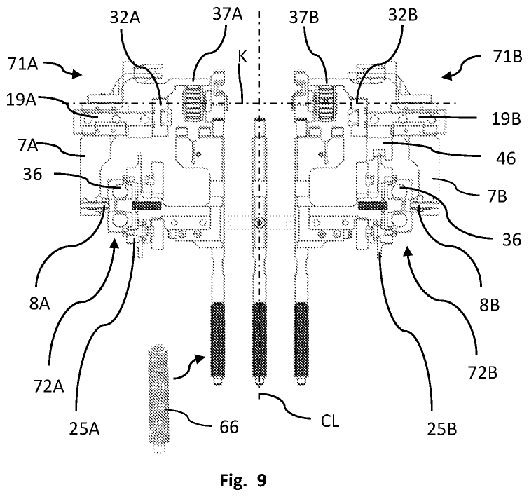

In the X-pitch direction, the PnP device 60 can accommodate any numbers of pickup tips 65 arranged in columns M, N, O, P, Q and so on. Each of columns M, N, O, P, Q can move along the X direction to either the “park area” or “active area”. As such, only pickup tips 65 at the “active area” will be utilized for picking up components while the pick-up tips at the “parking area” will not be in use. For pitch conversions in the X-pitch direction, each set of columns (or modules) M, N, O, P, Q can be moved to a pitch position along the X-pitch direction. Further, during operation of the device 60, it is also possible to remove any one of the pickup tips 65 suction portion using a quick release mechanism 66 (shown in FIG. 9) to further change the operational configuration of the active pickup tips 65 as desired by user.

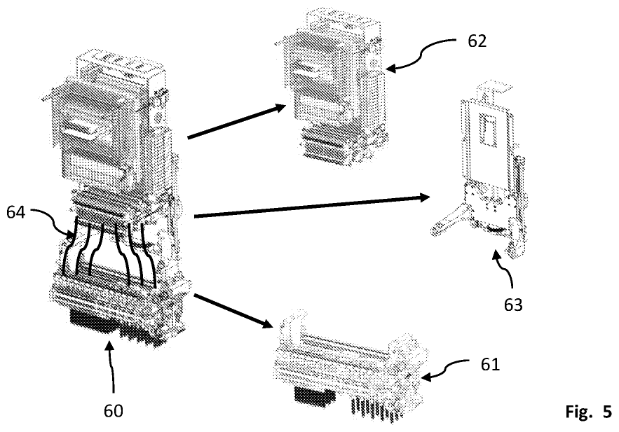

FIG. 5 shows a configurable PnP device 60 including an automatic pitch conversion unit 61 and a control-and-valve unit 62 attached to a chassis 63. Vacuum suction is provided by air tubes 64 connected between the control-and-valve unit 62 and the automatic pitch conversion unit 61 such that the pickup tips 65 are provided with vacuum suction to pick and hold electronics components from for example, a JEDEC tray 100 or other component carriers to another tray or inspection station 110. The control and valve unit 62 can be directly attached to the PnP device 60 to reduce response time but can also be located away from the PnP device 60 to reduce the weight of the assembly. When located away from the PnP device 60, the control-and-valve unit 62 may be located next (top, adjacent or bottom) to the PnP device 60. While this arrangement reduces the weight and size of the PnP device and can save power, the disadvantage is that the tubes will be lengthy and will require internal routing using cable chains to connect to the control-and-valve unit 62. Response time will therefore be longer and system throughput will drop. Therefore, flexibility of assembly is left to the user and/or machine capacity to determine.

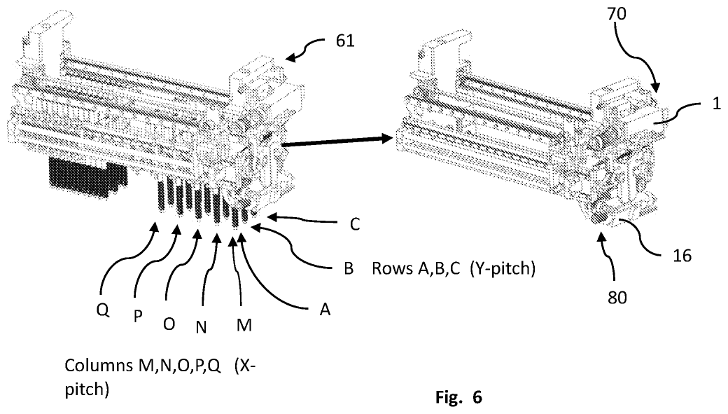

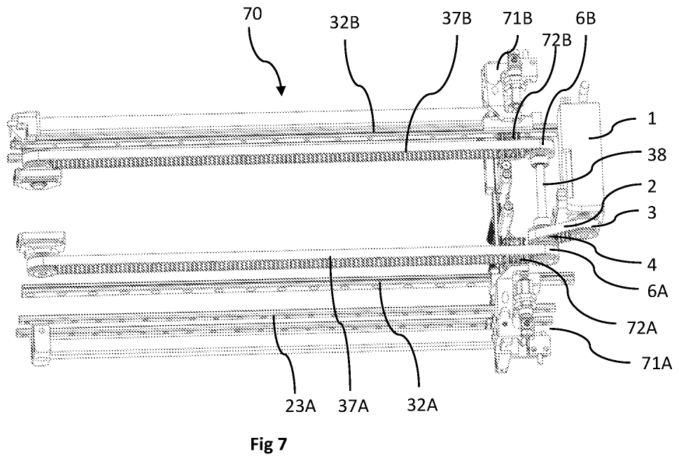

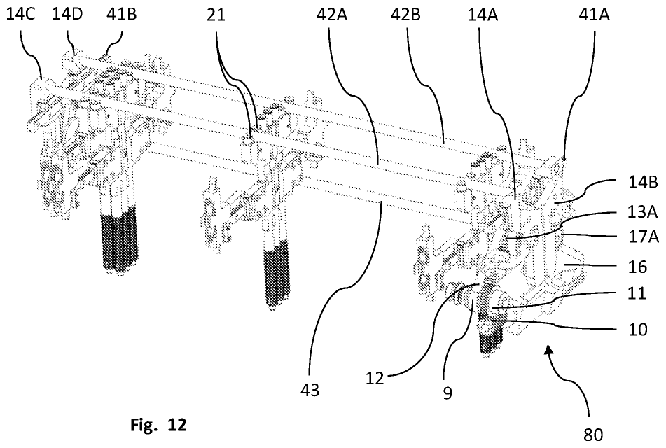

FIG. 6 shows the automatic pitch conversion unit 61 of FIG. 5 showing the X-pitch conversion mechanism 70 and Y-pitch conversion mechanism 80. There can be as many columns M,N,O,P,Q (and so on) as possible of active pickup tips (pickup tips grouped on the right of the automatic pitch conversion unit 61 in FIG. 6) limited only by machine capacity and user needs. This means that the columns M,N,O,P,Q of active pickup tips 65 are flexible and easily configured along the X-pitch direction in accordance with the tray matrix or inspection matrix when the machine is in operation. The X-pitch conversion mechanism 70 includes a drive motor 1 and drive elements to drive engagement arms 71 to move columns M,N,O,P,Q to their desired positions in the X-pitch direction (see FIG. 7). The Y-pitch conversion mechanism 80 includes a drive motor 16 and drive elements to move a pair of rods 42 for Y-pitch conversion for the rows A,B,C in the Y-pitch direction (see FIG. 12).

### X-Pitch Conversion Mechanism

As shown in FIGS. 7-10, the X-pitch drive motor 1 transfers motion via a plurality of motion transfer elements (timing pulley 3 at drive motor 1, timing belt 2, timing pulley 4) which are connected to drive timing pulley 6A. The drive motor 1 motion transfer elements are located at the right end portion of the automatic pitch conversion unit 61 as viewed in FIG. 7. In this way drive timing pulley 6A can move a timing belt 37A in a linear motion (left to right or vice versa) when drive motor 1 is rotated in a clockwise or counter-clockwise direction.

A transfer drive shaft 38 is rotatably attached to timing pulley 4 to transfer the drive motor 1 motions to another timing pulley 6B at another end of the right end portion (viewed from the right end portion of FIG. 7) of the automatic pitch conversion unit 61. In this way, timing pulley 6B can move a timing belt 37B in a linear motion (left to right direction or vice versa) when drive motor 1 is rotated in a clockwise or counter-clockwise direction synchronously with timing belt 37A.

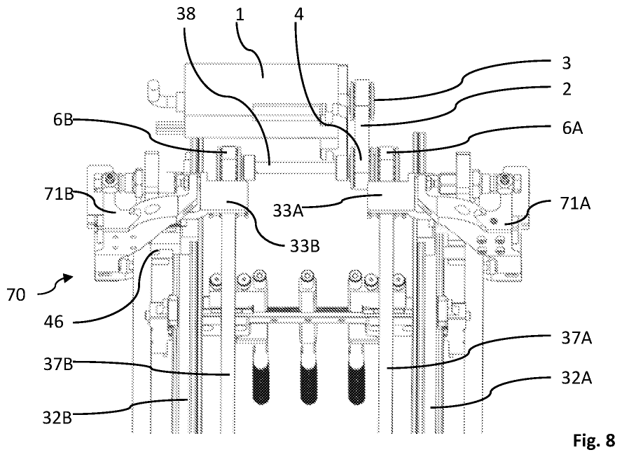

A right engagement arm 71A and a left engagement arm 71B is fixedly attached to the pair of timing belts 37A and 37B by clamps 33A and 33B respectively (see FIGS. 7 and 8). The right and left engagement arms 71A, 71B are slidably attached to respective pair of guide rails 32A and 32B so that the pair of timing belts 37A, 37B can move the right and left engagement arms 71A,71B along the guide rails 32A,32B. The right and left engagement arms 71A, 71B are situated opposite each other and along a common axis K (see FIG. 9). In this way, the right and left engagement arms 71A,71B can synchronously move together in the X-pitch direction from one end to the other end of the automatic pitch conversion unit 61 to move each of the pickup tips columns M,N,O,P,Q with respect to drive motor 1 rotations.

### Engage/Disengage Process to Move Columns M,N,O,P,Q

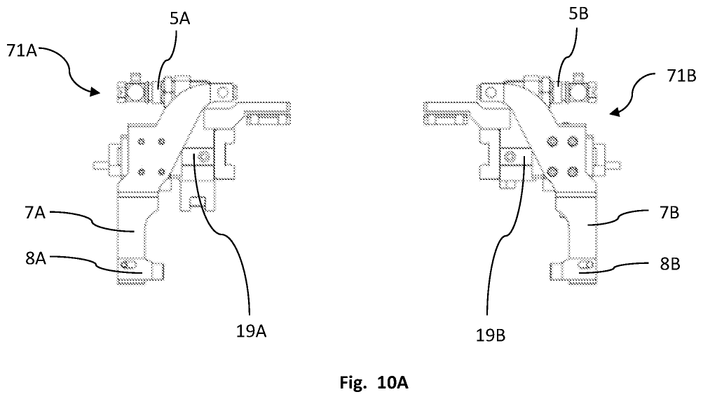

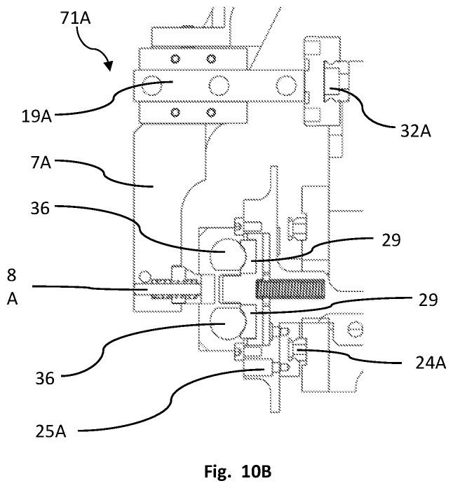

FIGS. 10A and 10B are various views showing details of the engagement arms 71A, 71B. The engagement arms 71A, 71B are identical to each other and includes pneumatic pin cylinders 5A,5B and pushers 7A,7B with a fingers 8A,8B and sliding guides 19A,19B. When a command is sent from the control and valve unit 62, cylinders 5A,5B will synchronously activate pushers 7A,7B such that fingers 8A,8B are movable forwards to engage or backwards to disengage pickup tip holders25A,25B along sliding guides 19A,19B. In this way, the engagement arms 71A,71B can be controlled to engage/disengage to/from pickup tip holders 25A,25B during X-pitch conversion.

FIG. 10B is a left section view showing the left engagement arm 71A. An upper and a lower pair of lock shafts 36 are located adjacent to the left engagement arm 71A. The lock shafts 36 are arranged in parallel, one above the other and are attached to the left and right side walls of the automatic pitch conversion unit 61, respectively. The pickup tip holder 25A is slidably held between the pair of lock shafts 36. Likewise, an upper and a lower pair of lock shafts 36 are located adjacent to the right engagement arm 71B. The pickup tip holder 25B is slidably held between this pair of lock shafts 36. Both the pickup tip holders 25A,25B are respectively engaged to the pickup tips columns M,N,O,P,Q on both sides i.e., pickup tips rows A and C (see FIGS. 2A,2B and 6). The pickup tip holders 25A, 25B includes a pair of friction blocks 29A,29B for locking and/or unlocking engagement with the lock shafts 36.

As shown in FIG. 10B, when the X-pitch conversion mechanism 70 is activated, spring loaded pusher finger 8A will be inserted into pickup tip holder 25A to release the friction blocks 29 from lock shafts 36. This action allows the pickup tips row M for example, held by pickup tip holders 25 to be moved in the X-direction to the desired X-pitch position along guides 32A,32B. Each of the pickup tip holders 25A,25B has a sensor for determining the coordinates of each of the pickup tips 65 of columns M,N,O,P,Q and rows A,B,C and so on. When the desired X-pitch position is reached, pusher finger 8 will be released and the pickup tips row M will be locked in the X-pitch position by the lock shafts 36 and friction blocks 29.

The process is repeated for pickup tips in column N and so on as programmed by the control unit 50. As the operation of the X-pitch conversion is conducted column by column, the X-pitch between each column of the pickup tips can be the same or differ from each other i.e., variable. For example, the pitch between column M and column N can be adjusted to say X-pitch1 while the pitch between column N and column O can be X-pitch1 or X-pitch2 and so on. Variable pitch adjustments advantageously allow the user freedom to configure as many formats/matrices as possible in relation to the type of usage of the PnP devices for transferring the components to other types of carriers and/or workstations with different formats/matrices.

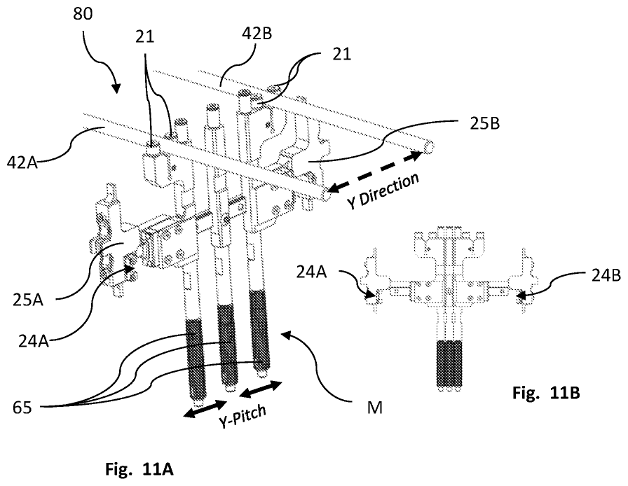

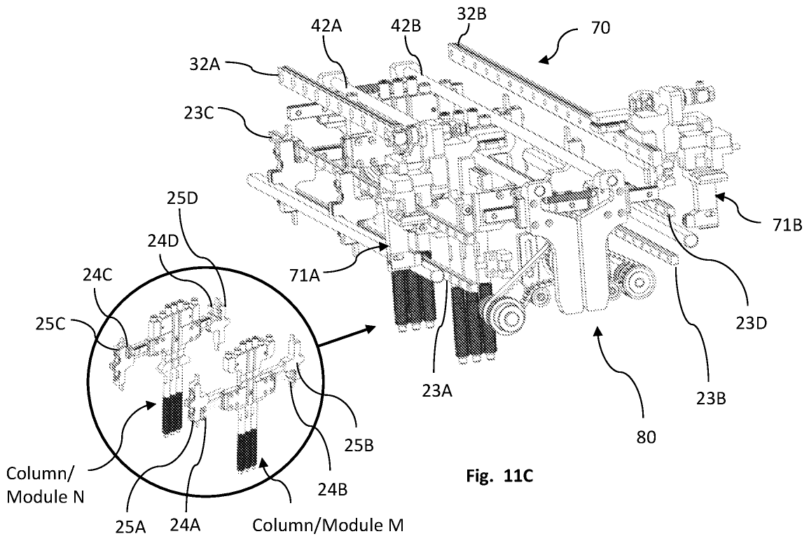

FIGS. 11A and 11B show a pair of bearing blocks 24A,24B attached to respective pickup tip holders 25A, 25B. The pickup tip columns M,N,O,P,Q are slidably moved in the X-pitch direction by engagement arms 71A,71B along a pair of guide rails 23A,23B (FIG. 11C) which extend longitudinally across the length of the pitch conversion unit 61. Linear Motion slides (e.g. Linear Motion Guide Rails comprising guide rails and bearing blocks) are usually utilised for this purpose as they are easily available and inexpensive to use. However, such off-the-shelf components have bearing blocks with minimum pitch lengths (e.g. 15.6 mm) which are the closest dimensions where the bearing blocks will touch one another and prevent further movement. This minimum pitch length may not be able to meet the X-pitch dimensions that are smaller (e.g. 8 mm). As such, an alternating arrangement of the pickup tips column M,N,O,P,Q may be utilised to overcome this constraint.

FIG. 11C shows a configuration having two pairs of guide rails 23A,23B and 23C, 23D in accordance with another embodiment. The two pairs of guide rails 23A, 23B, 23C, 23D may be arranged in a parallel manner and extend longitudinally across the length of the pitch conversion unit 61. The first pair of guide rails 23A, 23B is spaced apart from the second pair of guide rails 23C, 23D. Bearing blocks 24A,24B and 24C,24D which are attached to respective pickup tip holders 25A,25B and 25C,25D, are slidably attached to guide rails 23A,23B and 23C, 23D respectively. In this way, pickup tips column M may be carried by the first set of pickup tip holders 25A,25B that are slidably attached to the first set of bearing blocks 24A,24B. Similarly, the second column N of pickup tips may be carried by the second set of pickup tip holders 25C,25D that are slidably attached to the second set of bearing blocks 24C,24D. In this way, columns M and N operate independently of each other such that column N can be configured to move to an X-pitch position that is smaller than if both columns M and N are attached to the same guide rails 23A,23B. One skilled in the art will readily understand the benefits of this arrangement so that the X-pitch can be adjusted to a value that is as small as possible. Such an alternating pickup tip column arrangement can also be expanded to include multiple alternating pairs of guide rails to further decrease the X-pitch dimensions.

### Y-Direction Pitch Conversion Mechanism

FIG. 11A shows a three pickup tips column M in an open position and FIG. 11B shows the pickup tips 65 in a closed position (home position) in the Y-pitch direction. The pickup tips column assembly is held by the pickup tip holders 25A, 25B which rests on the pair of slidable guide rails 24A,24B (see FIGS. 7 and 10B)

As shown in FIGS. 12, 13 and 14, the Y-pitch conversion mechanism 80 includes a Y-pitch motor 16 for transferring motion to a pair of pitch rods 42A, 42B along guide rails 41A (right side of automatic pitch conversion unit 61) and 41B (left side of automatic pitch conversion unit 61) thereby moving row A and row C of the pickup tips columns M,N,O,P,Q to the desired Y-pitch.

The Y-pitch conversion mechanism 80 includes a drive motor 16 which drives a set of motion transfer elements (worm gear 10 at drive motor 16, pinion 11, timing pulley 9 and timing belt 12) to drive pulley 13A. Drive pulley 13A in turn moves Y-pitch arms 14A and 14B via link arm 39. The link arm 39A is rotatably pivoted at a center location of its longitudinal length such that a clockwise/counterclockwise rotation of drive pulley 13A will induce the ends of link arm 39 to slide along the slots of Y-pitch arms 14A,14B to drive pulley 13A and is slidably attached to the Y-pitch arms 14A and 14B via rotatable bearings (not shown) thereby translating the rotary motion of drive pulley 13A into linear motion to push Y-pitch arms 14A and 14B away or towards each other to provide the pitch distance adjustments (Y-pitch conversion). Note that row B of the rows A,B,C will be fixed in position along centre line CL (see FIG. 9) in a three-row pickup tip assembly. An optional resilient member (not shown) such as an extension spring can further be utilized to pull Y-pitch arms 14A,14B to the closed position (home position).

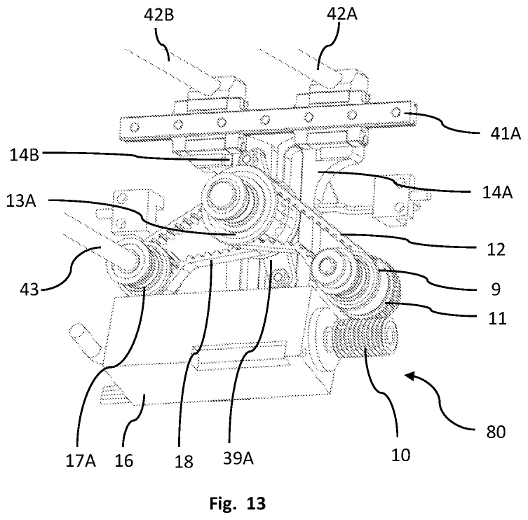

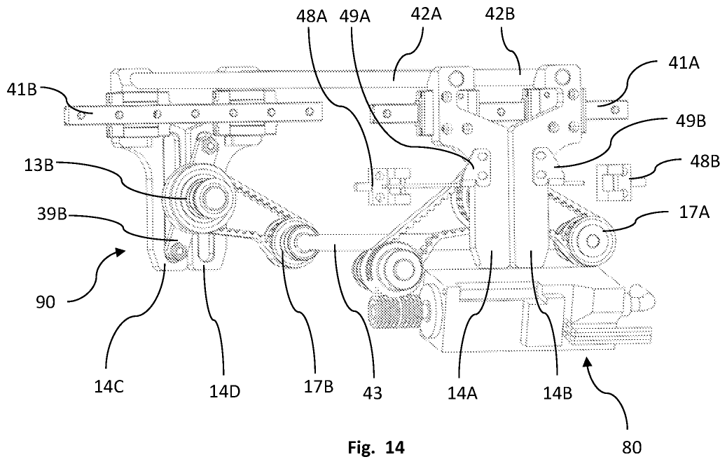

A balancing mechanism 90 having a set of motion transfer elements corresponding to transfer elements (timing pulley 3 at drive motor 1, timing belt 2, timing pulley 4) is mounted at the left end of the automatic pitch conversion unit 61. As shown in FIGS. 13 and 14, drive pulley 13A transfers motion to another drive pulley 17A via timing belt 18, transfer shaft 43 to link drive pulley 17A to transmit rotary motion from drive motor 16 to drive pulley 17B at the left end of the automatic pitch conversion unit 61, and to balancing mechanism Y-pitch arms 14C, 14D slidably attached to guide 41B via identical link arm 39B. The balancing mechanism 90 will operate in synchronous motion with the primary Y-pitch conversion mechanism 80 to ensure balance and stability when the Y-pitch conversion is in operation.

Referring again to FIGS. 11-14, each row of pickup tips A, B, C are slidably attached to pitch rods 42A,42B via bearing mountings 21. During Y-direction pitch conversion, pitch rods 42A,42B will move pickup tips rows A and C in a linear direction along the Y-direction guided by tracks 41A, 41B. All columns M,N,O,P,Q will be simultaneously moved for Y-pitch conversion, i.e., at the same time regardless of whether they are at parking area or at active area.

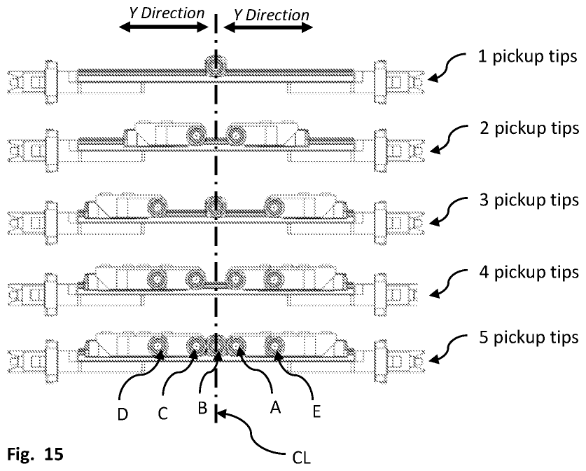

The preceding disclosure illustrates a three pickup tips row configuration. However, the numbers of active pickup tips 65 can be varied and their numbers are scalable and further adjusted according to the JEDEC tray or other types of carrier matrix. There are no limitations to the numbers of pickup tips 65 in the columns M,N,O,P,Q of each PnP device 60. FIG. 15 shows an example of the layout of different numbers of pickup tips 65 that can be configured by a user. For conversion, when it is an odd number (1, 3 or 5), the pickup tip at the centre position CL (see also FIG. 9) is fixed and the pickup tips on the left and the right of the centre position are movable along the Y-pitch direction to enable pitch conversion. When it is an even number of pickup tips (2, 4), all the pickup tips can be movable along the Y-pitch direction with centre position CL acting as reference position. The suction portion of the pickup tips can also be removed manually by user with a quick release mechanism 66 (see FIG. 9) as well to enable other pickup tip configurations for inspections and so on.

The numbers of rows of pickup tips in each column as shown in FIGS. 11A and 11B can be increased from a single row to as many rows as shown in FIG. 15. The pitch conversion can be similarly applied by increasing the length of the link arms 39A,39B as well as the numbers of pitch rods 42A,42B. Other mechanisms, for example pantograph mechanisms can also be used to provide the means to ensure the pitch between the rows of pickup tips D,C,B,A,E are equidistant from each other as will be understood by those skilled in the art.

In addition, after the Y and X pitch conversion for a product has been completed, it is still possible to change both the Y and X pitches after the components have been picked up by the PnP device and before being deposited into another tray (with different X & Y-pitches) or inspected at another workstation. However, such an on-the-fly conversion may not be advisable for X-pitch conversion as the X-pitch processing time needed may be excessive and thus resulting in reduced machine throughput. Such kinds of conversions should therefore be carried out only when there is an absolute need to do so, such as for example, when there are initial formatting errors or input errors. On the other hand, Y-pitch conversions can easily be done in a similar situation with a different Y-pitch tray or inspection station. On-the-fly pitch conversion can be illustrated in FIG. 1, where the Y-pitch in tray along line 101 can differ from the Y-pitch in tray along line 102. In this example, the PnP device 60(3) can pick components from JEDEC trays 100 (or other carriers) along line 101, conduct Y-pitch conversion on-the-fly and place them in JEDEC trays 100 (or other carriers with a different pitch from line 101) along line 102.

### Operation/Process

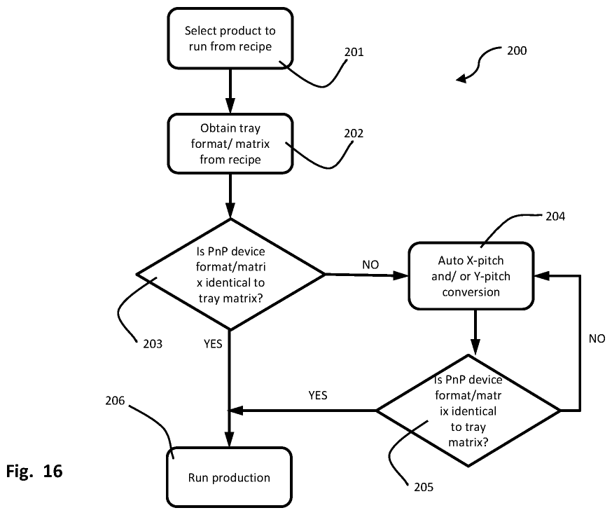

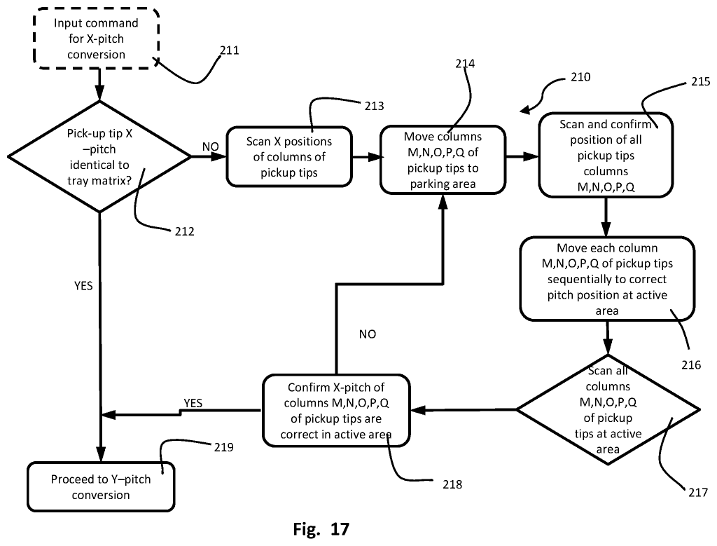

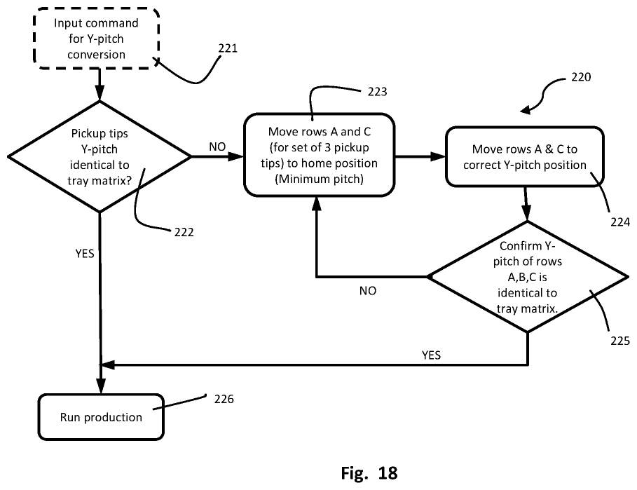

As shown in FIG. 16, production will commence if the X and Y pitches are identical between the tray matrices and the PnP devices. Automatic pitch conversion will commence if the pitches of PnP device and tray's matrix are different. The control system 50 will commence conversion for X-pitch as shown in FIG. 17 followed by Y-pitch as shown in FIG. 18.

FIG. 17 shows the process for X-pitch conversion. Control system 50 will first identify all columns M,N,O,P,Q and row A,B,C pickup tip positions. This is executed by a slot sensor 46 complete with a sensor flag (pickup tip holder 25B utilised as a sensor flag to save space) attached to the pickup tip holder 25A for column M as an example. The locations of the sensor 46 and sensor flag 25B is shown in FIG. 9. Sensor 46 is referenced to the right engagement arm 71B and left engagement arm 71A in the X-pitch direction to determine the positions of column M,N,O,P,Q pickup tip positions. If X-pitch conversion is required, the left engagement arm 71A and right engagement arm 71B will proceed to each column M,N,O,P,Q of pickup tips 65, unlock them one at a time and sequentially move them to the “Parking area” of the automatic pitch conversion unit 61.

At the “Parking area”, control system 50 will rescan and reconfirm columns M,N,O,P,Q positions. Upon confirmation, the left engagement arm 71A and right engagement arm 71B will engage pickup tip holders 25A,25B (or pickup tip holders 25C,25D if an alternating configuration is used) and move each column M,N,O,P,Q sequentially to their desired positions to the “Active area”, i.e., following the matrix of tray or carrier. Control system 50 will scan and confirm all positions again for every column M,N,O,P,Q upon meeting pitch position before disengaging arms 71A, 71B and moving to the next column of pickup tips. Upon completion of the X-pitch conversions, the process will proceed to the Y-pitch conversion.

The process for Y-direction automatic pitch conversion is shown in FIG. 18. The positions of the rows A,B,C are first confirmed by a slot sensor 48A and sensor flag 49A. The locations of the slot sensor 48A and sensor flag 49A are shown in FIG. 14. Control system 50 will move rows A and C to the home position first (closed position), before converting to the correct pitch position following the tray or carrier matrix. Control system 50 will scan and reconfirm all Y-pitch positions again for every row A,B,C upon reaching Y-pitch position.

After the X and Y pitch conversions are completed, the control system 50 will issue a command to system 10 for production run. When a different product is introduced (different tray or inspection matrices), the process will repeat for auto pitch conversions as illustrated in in FIGS. 16, 17 and 18.

The process steps of the automatic pitch conversion is illustrated below.

FIG. 16 shows the overall process flow 200 for automatic pitch conversion for the PnP device.

Step 201: User selects the product to run using the recipe 51 in control unit 50;
Step 202: Control unit 50 software will obtain the tray format/matrix information from the recipe 51;
Step 203: Determine whether the PnP device and the tray formats/matrices are identical. If they are identical, process will proceed to step 206 to run production;
Step 204: If the PnP device and the tray formats/matrices are not identical, control unit 50 will input command to conduct X-pitch and/or Y-pitch conversion on the PnP device;
Step 205: Upon completion of step 204, control unit 50 will again determine whether the PnP device format/matrix is identical with the tray format/matrix; If the PnP device and the tray formats/matrices are not identical, the process step will revert back to step 204;
Step 206: If the PnP Device and the tray formats/matrices are identical, system 10 will proceed to run production.

While the process steps refer to a tray format/matrix, a similar process will apply for a workstation format/matrix as will be well understood by those skilled in the art,

FIG. 17 shows the process flow for automatic X-pitch conversion 210.

Step 211: Control unit 50 inputs command for X-pitch conversion;
Step 212: Control unit 50 will determine if X-pitch is identical to tray matrix and proceed to Step 219 if X-pitch is identical;
Step 213: Control unit 50 will conduct a scan of the X positions of columns of pickup tips if X-pitch is not identical to tray matrix;
Step 214: Move all columns M,N,O,P,Q of pickup tips to parking area;
Step 215: Scan and confirm position of all pickup tips columns M,N,O,P,Q in parking area;
Step 216: Sequentially move each column of pickup tips to correct X-pitch position in active area;
Step 217: Scan all columns M,N,O,P,Q of pickup tips at active area;
Step 217: Confirm X-pitch positions of columns M,N,O,P,Q pickup tips are correct in active area, proceed to Step 214 if the X-pitch is incorrect;
Step 219: Proceed to Y-pitch conversion if all X-pitch positions of pickup tips for columns M,N,O,P,Q are correct.

FIG. 18 shows the process flow for automatic Y-pitch conversion 220.

Step 221: Control unit 50 inputs command for Y-pitch conversion;
Step 222: Scan and confirm Y-pitch position of pickup tips in rows A,B,C, if pickup tip Y-pitch is identical to tray matrix, proceed to run production at step 226;
Step 223: Move rows A & C to home position (minimum pitch) if Y-pitch is not identical to tray matrix;
Step 224: Move rows A and C to correct Y-pitch positions;
Step 225: Scan and confirm Y-pitch of rows A,B,C of pickup tips are correct in active area, proceed to Step 223 if the Y-pitch are incorrect;
Step 226: Proceed to run production if Y-pitch is correct.

The present invention offers several advantages. Firstly, the PnP devices can be located anywhere on the machine. Secondly, the numbers of transport lines for the trays and transfer lines for the PnP devices and pickup tips are expandable. These advantages effectively eliminate the need to maintain the many different conversion kits required by conventional PnP devices. The dual X and Y pitch conversion mechanisms integrated into the PnP device additionally provide quick response time during product change if pitch conversions are required in addition to an on-the-fly pitch conversion capability. These advantages collectively improve on the throughput of the system 10.

It will now be apparent that a a pick-and-place system, device and method having a plurality of pick-and-place stations and self-contained pick-and-place devices that are capable of automatic pitch conversions in X and Y coordinates has been described in the specification with sufficient particularity to be understood by one of ordinary skill in the art. Moreover, it will be apparent to those skilled in the art that various modifications, variations, substitutions, and equivalents exist for features of the device which do not materially depart from the scope of the invention.

It should be further appreciated by the person skilled in the art that variations and combinations of features described above, not being alternatives or substitutes, may be combined to form yet further embodiments falling within the intended scope of the invention.

1. A component pick-and-place system comprising:
a control unit;
at least one transport line for transporting a plurality of component trays; and
at least one transfer line for transferring a plurality of pick-and-place (PnP) devices;
wherein each of the plurality of PnP devices comprises:
a control and valve unit;
an automatic pitch conversion unit having at least one column and at least one row of pickup tips positional at a parking area and an active area, the automatic pitch conversion unit further comprising:
a X-pitch conversion mechanism comprising:
a first drive motor;
a plurality of movement transfer elements for transferring rotary motions of the first drive motor to cause a pair of X-pitch bands to move in a linear direction;
a pair of engagement arms slidably engaged to the pair of X-pitch bands for sequentially engaging each of the at least one column of pickup tips to move to a desired X-pitch position;
a Y-pitch conversion mechanism comprising:
a second drive motor;
a plurality of movement transfer elements for transferring rotary movements of the second drive motor to a pair of Y-pitch arms to cause a pair of Y-pitch rods to move in a linear direction;
a pair of pickup tip holders slidably engaged to the pair of Y-pitch rods for simultaneously moving the at least one row of pickup tips to a desired Y-pitch position.

2. The system of claim 1, wherein the X-pitch mechanism comprises a first pair of guide rails and each of the plurality of columns of pickup tips is sequentially moved to the X-pitch position along the first pair of guide rails.

3. The system of claim 2, wherein the X-pitch mechanism further comprises a second pair of guide rails spaced apart from the first pair of guide rails and each of the plurality of columns of pickup tips is sequentially moved to the X-pitch position along the second pair of guide rails.

4. The system of claim 3, wherein each of the plurality of columns of pickup tips is sequentially moved along the first pair of guide rails followed by the second pair of guide rails, wherein the X-pitch between each column is variable.

5. The system of claim 1, wherein each of the plurality of PnP devices is configured to pick components from the component trays along the transport line, conduct Y-pitch conversion on-the-fly and place the components in the component trays along another transport line.

6. The system of claim 5, wherein the Y-pitches along the transport lines are different.

7. The system of claim 1, further comprising a programmable software recipe configured to execute commands for X-pitch and Y-pitch conversions.

8. The system of claim 7, wherein the X-pitch conversion mechanism further comprises one or more column sensors configured to determine the actual positions of the pickup tips in an X-pitch direction and wherein the Y-pitch conversion mechanism further comprises one or more row sensors configured to determine the actual positions of the pickup tips in a Y-pitch direction.

9. The system of claim 8, wherein a suction portion of each pickup tip is configured to be removed with a quick release mechanism.

10. The system of claim 9, wherein each of the pair of engagement arms comprises a pin cylinder and a pusher, and wherein the control and valve unit is configured to activate the pin cylinder to enable the pusher to engage or disengage the pair of engagement arms.

11. The system of claim 1, wherein each of the at least one row of pickup tips are adapted to be slidably attached to the pair of Y-pitch rods such that each of the at least one row of pickup tips are simultaneously moved for Y-pitch conversion.

12. The system of claim 11, wherein the Y-pitch conversion mechanism comprises one or more link arms adapted to transfer rotary movement of the second drive motor to the pair of Y-pitch arms, and wherein the length of the one or more link arms is extendible to facilitate an increase in the numbers of rows of pickup tips.

13. The system of claim 12, further comprising a balancing mechanism adapted to be in synchronous motion with the Y-pitch conversion mechanism, the balancing mechanism being connected to the Y-pitch conversion mechanism via a shaft.

14. The system of claim 1, wherein the automatic pitch conversion unit further comprises a pantograph mechanism configured to keep the pitch between each row of pickup tips equidistant from each other.

15. A pick-and-place (PnP) device for transferring semiconductor components comprising:
a plurality of pick-and-place (PnP) modules, each PnP module comprising at least three pick-and-place (PnP) heads;
a transfer mechanism for moving each of the plurality of PnP modules to a component X-pitch position above a tray or workstation, the transfer mechanism comprising:
a first drive motor;
a plurality of movement transfer elements for transferring rotary motions of the first drive motor to cause a pair of X-pitch bands to move in a linear direction; and
a pair of engagement arms slidably engaged to the pair of X-pitch bands for sequentially engaging each of the plurality of PnP modules to move to a component X-pitch position; and
a pitch adjustment mechanism for adjusting the Y-pitch of the at least three pick-and-place heads, the pitch adjustment mechanism comprising:
a second drive motor;
a plurality of movement transfer elements for transferring rotary movements of the second drive motor to a pair of Y-pitch arms to cause a pair of Y-pitch rods to move in a linear direction; and a pair of pickup tip holders slidably engaged to the pair of Y-pitch rods for simultaneously moving the plurality of rows of pickup tips to a desired Y-pitch position.

16. The PnP device of claim 15, wherein the transfer mechanism comprises a first pair of guide rails and each of the plurality of PnP modules is sequentially moved to the X-pitch position along the first pair of guide rails.

17. The PnP device of claim 16, wherein the transfer mechanism further comprises a second pair of guide rails and each of the plurality of PnP modules is sequentially moved to the X-pitch position along the second pair of guide rails.

18. The PnP device of claim 17, wherein each of the plurality of PnP modules is sequentially moved along the first pair of guide rails followed by the second pair of guide rails, and wherein the X-pitch between each column is variable.

19. The pick-and-place (PnP) device of claim 15, wherein the pitch adjustment mechanism further comprises a pair of pickup tip holders slidably engaged to the pair of Y-pitch rods for simultaneously moving the plurality of rows of pickup tips to a desired Y-pitch position.

20. The pick-and-place (PnP) device of claim 15, wherein the pitch adjustment mechanism comprises one or more link arms adapted to transfer rotary movement of the second drive motor to the pair of Y-pitch arms, and wherein the length of the one or more link arms is extendible to facilitate an increase in the numbers of rows of pickup tips.

21. A method of automatic pitch conversion for a component pick-and-place system, the method comprising the steps of:
(a) selecting the component to run with the recipe in the control unit;
(b) obtaining the tray format or matrix information from the recipe;
(c) determining with the control unit, whether the X and Y pitches of the tray matrix are identical to the PnP device; and
(d) inputting a command with the control unit to carry out X-pitch and/or Y-pitch conversion on the PnP device when the X and Y pitches are determined not to be identical.

22. The method of claim 21, further comprising the step of moving each column of pickup tips to a parking area of the PnP device, and thereafter scanning to determine the X-pitch position of the pickup tips in the parking area.

23. The method of claim 22, further comprising the step of sequentially moving each column of pickup tips from the parking area to the correct X-pitch position in the active area.

24. The method of claim 23, further comprising the step of scanning each column of pickup tips at the active area to confirm the X-pitch positions of the pickup tips.

25. The method of claim 24, further comprising the step of moving each row of pickup tips to a home position whereby the Y-pitch between each pickup tip is at a minimum.

26. The method of claim 25, further comprising the step of simultaneously moving each row of pickup tips to the correct Y-pitch positions.

27. The method of claim 26, further comprising the step of scanning each row of pickup tips to confirm that the pickup tips are in the correct Y-pitch positions in the active area.

28. The method of claim 27, wherein the control unit is configured to input a command to carry out X-pitch and/or Y-pitch conversion on the PnP device when the X and/or Y pitches are still determined not to be identical.
